(19) United States
(12) Patent Application Publication
(10) Pub. No.: US 2007/0004188 A1
(43) Pub. Date: Jan. 4, 2007

(54) Method for fabricating semiconductor device

(75) Inventors: Jong-Man Kim, Kyoungki-do (KR); Weon-Joon Suh, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/408,207

(22) Filed: Apr. 19, 2006

(30) Foreign Application Priority Data
Jun. 30, 2005 (KR) 2005-0057914

(51) Int. Cl. H01L 21/3205

(52) U.S. Cl. 438/589

(57) ABSTRACT

A method for fabricating a semiconductor device is provided. The method includes: forming a sacrificial layer over a semiconductor substrate; patterning the sacrificial layer and the substrate to make openings; forming a conductive layer partially buried in the openings to form a gate; and removing the patterned sacrificial layer.

### BACKGROUND

The present invention relates to a method for fabricating a semiconductor device; and, more particularly, to a method for forming a gate in a semiconductor device using a damascene process.

Recently, as semiconductor devices have become highly integrated, a transistor structure having a recess channel has been suggested. The recess channel refers to a gate formed in a recess in a substrate. Herein, the recess is where a transistor channel is to be formed to increase an effective channel length. Thus, a punch-through effect, where impurities of a source and a drain are diffused to the side, is improved, and the distance between the source and the drain is substantially widened.

Also, source and drain junction regions and the channel region are formed in an elevated structure, minimizing a junction leakage caused by a channel doping. Ultimately, this elevated structure helps the large scale of integration of the semiconductor device.

The recess channel is formed before a gate electrode is formed. A precise overlay is generally required to form the recess channel at the bottom of the gate electrode. Patterning for forming the recess channel is in a line/space form and typically requires critical dimensions (CD) of an opening smaller than those of a gate pattern. Thus, after exposure and development processes, critical dimensions of a large photoresist pattern and a small space region, which is the recess region, ranging from approximately 30 nm to approximately 50 nm should be obtained. Due to the recent large scale of integration for memory cells, critical dimensions of the patterning for forming recess channels are gradually becoming smaller. Thus, it has become difficult to obtain the necessary critical dimensions in a 60 nm dynamic random memory (DRAM) device photo process.

Although semiconductor devices have become highly integrated, it is difficult for an exposure device to obtain critical dimensions below 60 nm. Thus, difficulties, such as not being able to obtain desired values of exposure latitude (EL) and depth of focus, occur.

FIG. 1A is a cross-sectional view of a semiconductor device fabricated according to a conventional method, and FIGS. 1B and 1C are transmission electron microscopy (TEM) pictures illustrating a semiconductor device fabricated according to a conventional method.

As shown in FIG. 1A, device isolation regions 12 are formed in a substrate 11 by using a shallow trench isolation (STI) method. A recess mask, although not shown, for forming a recess R is formed on a predetermined region. Then, the substrate 11 is selectively etched to a predetermined depth using the recess mask as an etch mask to form the recess R.

Subsequently, the recess mask is removed, and a gate oxide layer 13 is formed over the substrate 11 and the recess R. Generally, the gate oxide layer 13 is formed by a thermal oxidation method.

A recess gate RG including a patterned polysilicon layer 14, a patterned silicide layer 15, and a gate hard mask 16 is formed in the gate oxide layer 13. In more detail, although not illustrated, a polysilicon layer for use as a gate conductive layer, a silicide layer, a gate hard mask layer are sequentially formed on the gate oxide layer 13. Next, a photoresist pattern is formed on the gate hard mask layer, and the gate hard mask layer is etched using the photoresist pattern as an etch mask. Then, the photoresist pattern is stripped.

The silicide layer, the polysilicon layer, and the gate oxide layer 13 are etched using the gate hard mask 16 as an etch mask to form the recess gate RG.

Herein, as the semiconductor device has become highly integrated, the recess gate RG has also shrunk, and thus, patterning the recess gate RG under 70 nm has become difficult. Also, a misalignment is generated between the recess R and the recess gate RG due to the shrunken recess gate RG.

On the other hand, FIGS. 1B and 1C are micrographic views illustrating an electrical analysis of a cell related to single fail defect depending on the recess gate misalignment. Herein, a reference numeral 11 refers to a substrate, and a reference numeral 12 refers to device isolation regions. Boron concentration, obtained by a C-halo ion implantation process of a bit line (BL) node, is further increased near a bottom corner of the recess gate, and it is disadvantageous for a landing plug contact (LPC) to be opened. That is, a threshold voltage Vₛₐₜ, where Vₛₐₜ=1C−1K, becomes large.

Herein, 1C represents a threshold voltage of a right transistor, and 1K is an average process control monitor (PCM) value of a left transistor and the right transistor. If a fail occurs in the right transistor in each address, Vtₛₐₜ becomes large and the Vₛₐₜ of the right transistor becomes small.

When the boron concentration, obtained by the C-halo ion implantation process of the bit line (BL) node, is further increased near the bottom corner of the recess gate, which is a portion where an electric field is diffused, an on/off characteristic of the transistor is determined as the boron concentration changes.

Furthermore, the threshold voltage of the transistor is increased in the portions with the higher boron concentration, and the higher boron concentration shows that the boron is more likely to diffuse toward a storage node. Even if diffusion does not occur, the electric field near the BL node functions to ascend an electric field near the storage node. Thus, it is disadvantageous for refresh.

Moreover, the high threshold voltage is disadvantageous for both a write time (TAR) and a refresh time (TREE). For a DC recess gate, easy-prove-test 1 (EPIC) is negatively affected if the DC recess gate deviates more than ±15 nm. For a NOVA recess gate, EPIC is negatively affected also if the NOVA recess gate deviates more than ±15 nm.

Although a field center for each lot is shifted 10 nm on average, the recess gate needs to be kept under a deviation of ±15 nm at the maximum.

Due to the misalignment between the recess and the recess gate, limitations such as a void generation occurs while forming a subsequent inter-layer insulation layer, and thus, production yield is decreased and operation characteristics of the device is deteriorated.

### SUMMARY OF THE INVENTION

It is, therefore, an object of the present invention to provide a method for fabricating a semiconductor device capable of preventing a shrink of a gate line and improving a gate line misalignment.

In accordance with an aspect of the present invention, there is provided a method for fabricating a semiconductor device, including: forming a sacrificial layer over a semiconductor substrate; patterning the sacrificial layer and the substrate to make openings; forming a conductive layer partially buried in the openings to form a gate; and removing the patterned sacrificial layer.

### BRIEF DESCRIPTION OF THE DRAWINGS

The above and other objects and features of the present invention will become better understood with respect to the following description of the specific embodiments given in conjunction with the accompanying drawings, in which:

FIG. 1A is a cross-sectional view illustrating a conventional method for fabricating a semiconductor device;

FIGS. 1B and 1C are micrographic views illustrating a conventional method for fabricating a semiconductor device; and

FIGS. 2A to 2I are cross-sectional views illustrating a method for fabricating a semiconductor device in accordance with a specific embodiment of the present invention.

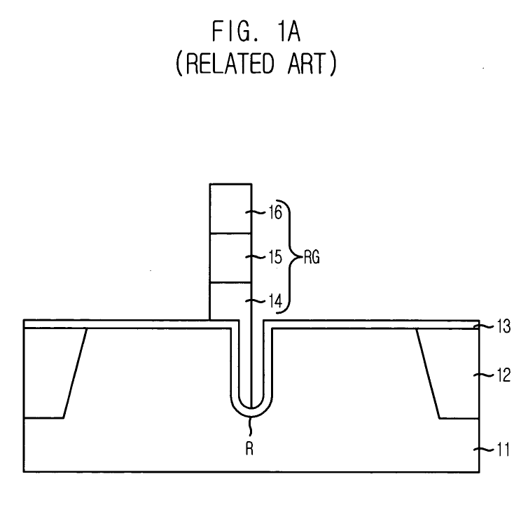

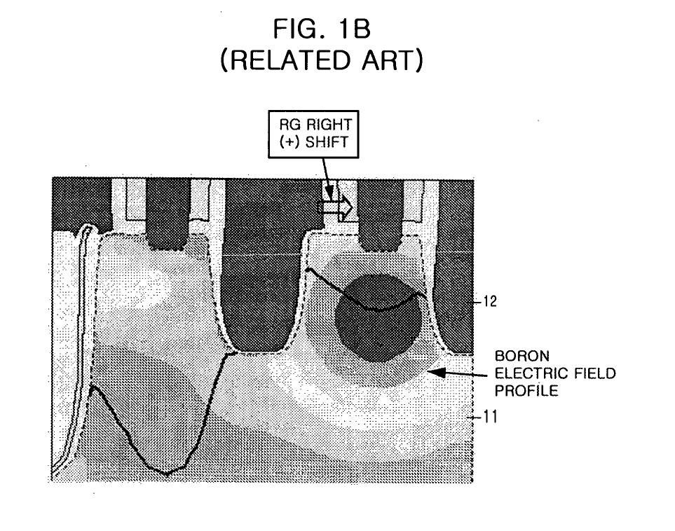

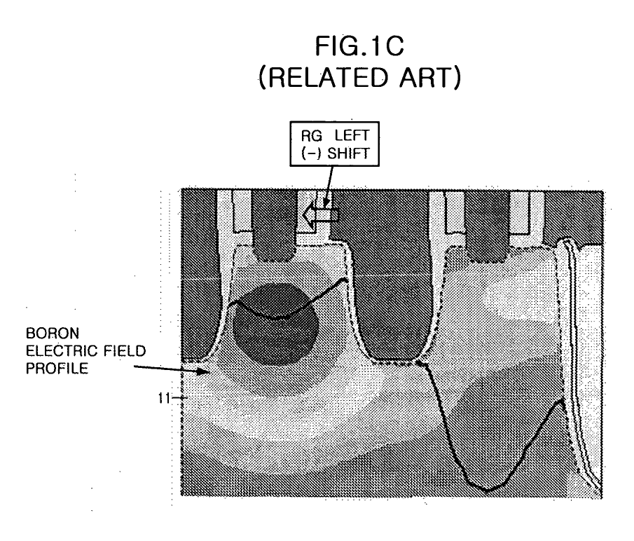

### DETAILED DESCRIPTION OF EMBODIMENTS

A method for fabricating a semiconductor device in accordance with specific embodiments of the present invention will be described in detail with reference to the accompanying drawings.

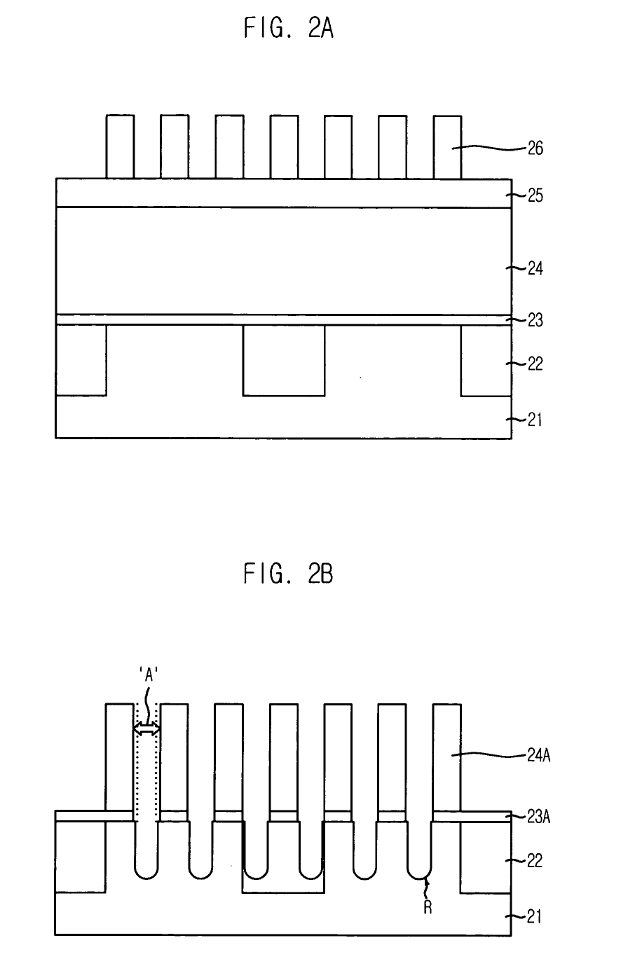

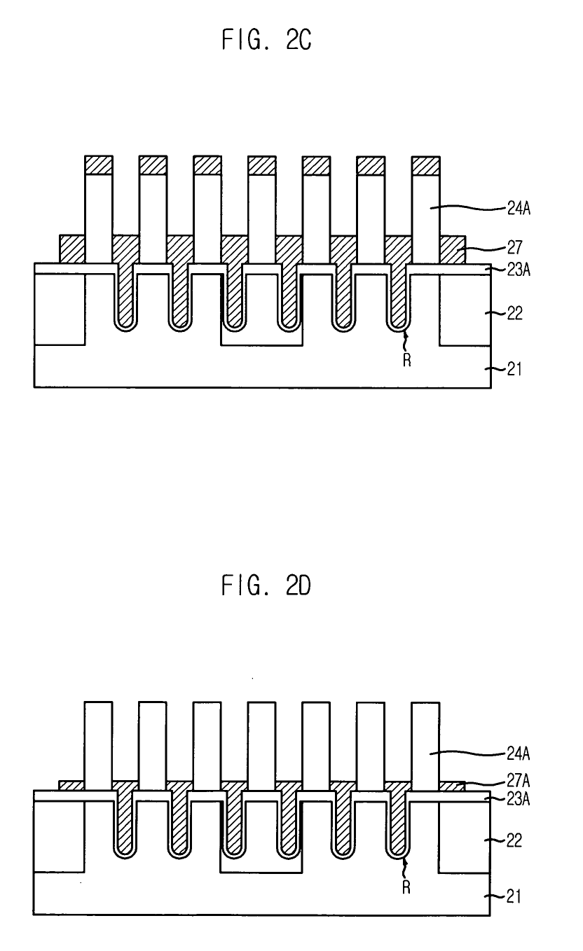

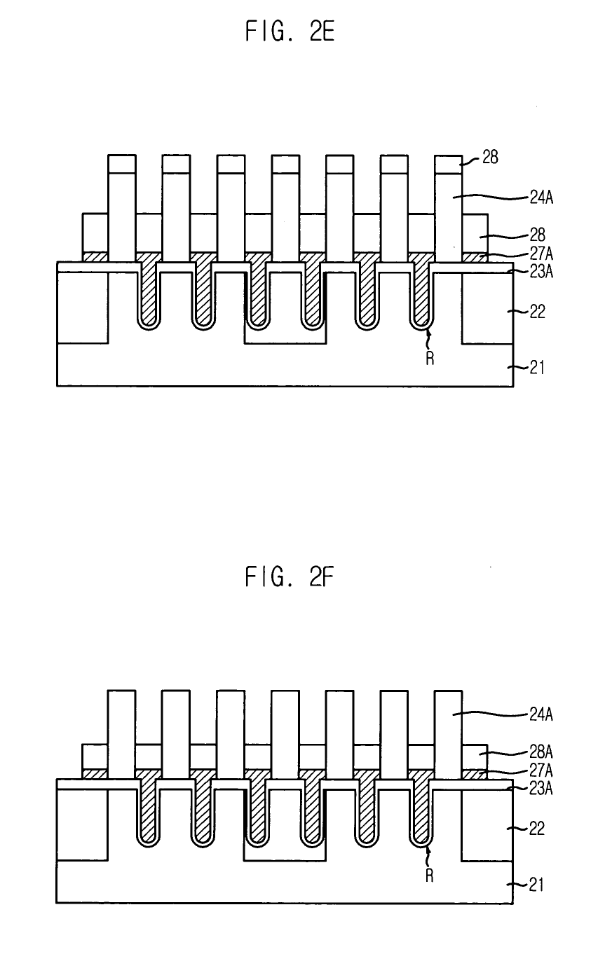

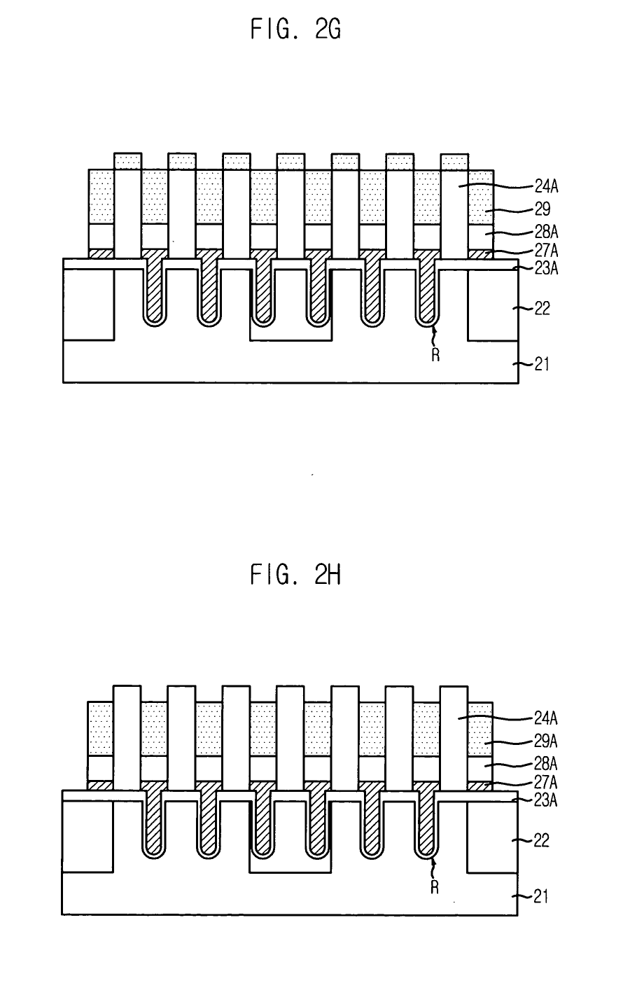

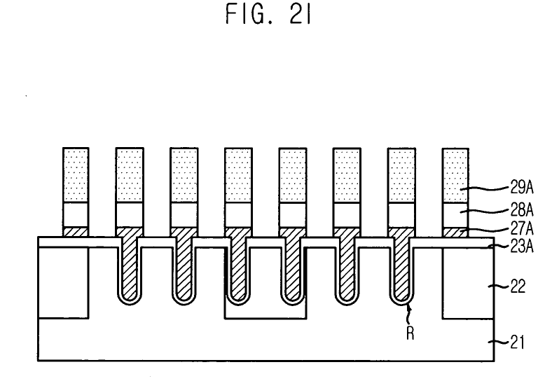

FIGS. 2A to 2I are cross-sectional views illustrating a method for fabricating a semiconductor device in accordance with a specific embodiment of the present invention.

As shown in FIG. 2A, device isolation regions 22 are formed in a substrate 21 using a shallow trench isolation (STI) method, and a gate oxide layer 23 is formed over the substrate 21 and the device isolation regions 22. Generally, the gate oxide layer 23 is formed by employing a thermal oxidation method.

Subsequently, a sacrificial layer 24 is formed over the gate oxide layer 23. The sacrificial layer 24 functions as a mask for use in recess formation, and is removed in a subsequent process. Also, the sacrificial layer 24 is formed by employing one of an oxide layer and a nitride layer. In this specific embodiment, an oxide layer is employed as the sacrificial layer 24 with a thickness ranging from approximately 1,500 Å to approximately 2,500 Å.

On the other hand, the sacrificial layer 24 is formed by employing an oxide layer of spin on glass (SOG) type or a high aspect ratio process (HARP) type. The oxide layer of these types is easily etched by a wet or dry etching process. For this reason, an annealing process is performed on the oxide layer at a temperature ranging from approximately 500° C. to approximately 1,000° C., so that the oxide layer can endure the etching process.

Next, a hard mask 25 is formed over the sacrificial layer 24. The hard mask 25 is formed by employing one of a polysilicon layer and a nitride layer. Then, a photoresist pattern 26 is formed over portions of the hard mask 25.

As shown in FIG. 2B, the hard mask 25 is etched using the photoresist pattern 26 as an etch mask. Then, the photoresist pattern 26 is removed.

Subsequently, the sacrificial layer 24 is etched using the etched hard mask 25 as an etch mask to thereby form a sacrificial pattern 24A. Then, the etching continues to etch the gate oxide layer 23 and the substrate 21 to thereby form a patterned gate oxide layer 23A and recesses ‘R’.

Furthermore, a wet etching or a cleaning process is performed on the above resulting substrate structure to etch sidewalls of the sacrificial pattern 24A, so that as expressed with a reference denotation ‘A’in FIG. 2B, a line width between the sacrificial patterns 24A is widened. Thus, an effective channel length is increased, improving a refresh characteristic. Even after the wet etching or the cleaning process is performed, the line width may still remain identical to the width of the recesses R. Therefore, a width of subsequent recess gates (to be formed in FIG. 2I) can be substantially identical or wider than the width of the recesses R.

On the other hand, a wet etching solution used in the wet etching process uses a mixture of HFₓ/NHF_{4y}/H₂O_{z}. Herein, x, y, and z representing each of the corresponding atomic composition ratios are in a range of approximately 1 to 2:4 to 6:100 to 500, respectively. The wet etching is performed for approximately 1 minute to approximately 5 minutes.

As shown in FIG. 2C, a thermal oxidation process is performed to form another gate oxide layer on surfaces of the recesses R. Herein, the other gate oxide layer is not denoted with a reference numeral, because the other gate oxide layer is formed with the same material as the patterned gate oxide layer 23A, and will be treated as a part of the patterned gate oxide layer 23A.

Furthermore, a polysilicon layer 27 is formed as a first conductive layer of the subsequent recess gates over the above resulting substrate structure. Herein, the polysilicon layer 27 is formed to partially fill spaces between the sacrificial patterns 24A, and portions of the polysilicon layer 27 formed on the sacrificial pattern 24A have a thickness smaller than the portions of the polysilicon layer 27 formed in the recesses R.

As shown in FIG. 2D, an etch-back process without using a mask is performed to remove the portions of the polysilicon layer 27 formed on the sacrificial pattern 24A. At this time, certain portions of a patterned polysilicon layer 27A formed in the recesses are etched as well.

As shown in FIG. 2E, a tungsten silicide layer 28 is formed as a second conductive layer over the above resulting substrate structure. Herein, the tungsten silicide layer 28 is formed to partially fill the spaces between the sacrificial patterns 24A, and portions of the tungsten silicide layer 28 formed on the sacrificial pattern 24A have a thickness smaller than the portions of the tungsten silicide layer 28 formed in the recesses R.

On the other hand, although tungsten silicide is employed as the second conductive layer, the second conductive layer can be formed by employing one selected from the group consisting of tungsten (W), tungsten nitride (WN), titanium nitride (TiN), titanium (Ti), molybdenum (Mo), tantalum (Ta), gold (Au), and silver (Ag).

As shown in FIG. 2F, an etch-back process or chemical mechanical polishing (CMP) process without using a mask is performed to remove the portions of the tungsten silicide layer 28 formed on the sacrificial pattern 24A. At this time, certain portions of a patterned tungsten silicide layer 28A formed in the recesses are etched as well.

As shown in FIG. 2G, a gate hard mask 29 is formed over the above resulting substrate structure. The gate hard mask 29 includes a nitride layer. Herein, the gate hard mask 29 is formed to fill the spaces between the sacrificial patterns 24A, and portions of the gate hard mask 29 formed on the sacrificial pattern 24A have a thickness smaller than the portions of the gate hard mask 29 formed in the recesses R.

As shown in FIG. 2H, an etch-back process without using a mask is performed to remove the portions of the gate hard mask 29 formed on the sacrificial pattern 24A. At this time, certain portions of a patterned gate hard mask 29A formed in the recesses are etched as well.

As shown in FIG. 2I, a wet dip out process is performed to remove the sacrificial pattern 24A, and thus, recess gates including the patterned gate oxide layer 23A, the patterned polysilicon layer 27A, the patterned tungsten silicide layer 28A, and the patterned gate hard mask 29A are formed.

Although the specific embodiment of the present invention describes the method for forming the recess gates by sequentially performing: the formation of the polysilicon layer; the etch-back process for the polysilicon layer; the formation of the tungsten silicide layer; the etch-back process for the tungsten silicide layer; the formation of the gate hard mask; and the etch-back process for the gate hard mask, it is possible to form the recess gates by forming the polysilicon layer, the tungsten silicide layer, and the gate hard mask in sequential order, and then performing the etch-back process.

By employing a damascene process during the recess gate formation, an advantageous gate line patterning under 70 nm is achieved. Also, the misalignment caused by a gate line shrink between the gate and the recess is prevented, such that gate resistance is reduced. Thus, device characteristics are improved.

In accordance with the specific embodiment of the present invention, difficulties with respect to gate line patterning under 70 nm are eased by employing the damascene process, and thus, the misalignment between the gate and the recess caused by the gate line shrink is improved.

Furthermore, the gate conductive layer is formed with low resistance material and the gate line patterning is improved, resulting in a lowered gate line height. Thus, it is advantageous for a subsequent oxide layer to be formed. That is, distinct benefits can be obtained with respect to a void.

The present application contains subject matter related to the Korean patent application No. KR 2005-57914, filed in the Korean Patent Office on Jun. 30, 2005, the entire contents of which being incorporated herein by reference.

While the present invention has been described with respect to certain specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a sacrificial layer over a semiconductor substrate;
patterning the sacrificial layer and the substrate to make openings;
forming a conductive layer partially buried in the openings to form a gate; and
removing the patterned sacrificial layer.

2. The method of claim 1, further comprising performing a wet etching or cleaning process on the patterned sacrificial layer to increase a line width of the openings.

3. The method of claim 1, wherein the forming of the sacrificial layer includes one selected from the group consisting of a spin on glass (SOG) layer, a high aspect ratio process (HARP) layer, and a nitride-based layer.

4. The method of claim 1, further comprising performing an annealing process after the sacrificial layer is formed.

5. The method of claim 4, wherein the annealing process is performed at a temperature ranging from approximately 500° C. to approximately 1,000° C.

6. The method of claim 2, wherein the wet etching of the patterned sacrificial layer includes using an etching solution with a mixture including hydrogen fluoride (HFₓ), NHF_{4y}, and water (H₂O_{z}) being mixed in a predetermined composition ratio.

7. The method of claim 6, wherein the predetermined composition ratio of HFₓ, NHF_{4y}, and H₂O_{z}, is obtained when x, y, and z representing respective atomic composition ratios are in a range of approximately 1 to 2:4 to 6:100 to 500, respectively.

8. The method of claim 6, wherein the wet etching of the patterned sacrificial layer is performed for approximately 1 minute to approximately 5 minutes.

9. The method of claim 1, wherein the forming of the conductive layer partially buried in the openings includes:
forming a conductive layer over the openings and the patterned sacrificial layer;
removing the conductive layer formed over the patterned sacrificial layer;
forming a gate hard mask over the conductive layer buried in the openings; and
removing the gate hard mask formed over the patterned sacrificial layer.

10. The method of claim 9, wherein the removing of the conductive layer and the gate hard mask is performed using an etch-back process or chemical mechanical polishing (CMP) process.

11. The method of claim 1, wherein the forming of the conductive layer partially buried in the openings includes sequentially forming a conductive layer and a gate hard mask in the openings, and removing the conductive layer and the gate hard mask formed over the patterned sacrificial layer.

12. The method of claim 11, wherein the removing of the conductive layer and the gate hard mask is performed using an etch-back process or CMP process.

13. The method of claim 9, wherein the conductive layer includes one selected from the group consisting of polysilicon, tungsten silicide, tungsten, tungsten nitride, titanium nitride, titanium, molybdenum, tantalum, gold, silver, and a combination thereof.

14. The method of claim 11, wherein the conductive layer includes one selected from the group consisting of polysilicon, tungsten silicide, tungsten, tungsten nitride, titanium nitride, titanium, molybdenum, tantalum, gold, silver, and a combination thereof.
